(19) United States
(12) Patent Application Publication
(10) Pub. No.: US 2009/0200683 A1
(43) Pub. Date: Aug. 13, 2009

(54) INTERCONNECT STRUCTURES WITH PARTIALLY SELF ALIGNED VIAS AND METHODS TO PRODUCE SAME

(75) Inventors: Matthew Earl Colburn, Hopewell Junction, NY (US); Nicholas C. Fuller, Ossining, NY (US); Elbert Huang, Carmel, NY (US); Satyanarayana V. Nitta, Poughquag, NY (US)

Correspondence Address: NUGENT & SMITH, LLP, 91 FOREST BOULEVARD, SUITE 100, ARDSLEY, NY, 10502, US

(73) Assignee: International Business Machines Corporation, Armonk, NY (US)

(21) Appl. No.: 12/030,756

(22) Filed: Feb. 13, 2008

(51) Int. Cl. H01L 23/48; H01L 21/4763

(52) U.S. Cl. 257/774; 438/637; 257/E23.01; 257/E21.495

(57) ABSTRACT

An interconnect structure having partially self aligned vias with an interlayer dielectric layer on a substrate, containing at least two conducting metal lines that traverse parallel to the substrate and at least two conducting metal vias that are orthogonal to the substrate. A method of producing the self aligned vias by depositing an interlayer dielectric layer onto a substrate, depositing at least one hardmask onto the interlayer dielectric layer, lithographically forming a via pattern with elongated via features and lithographically forming a line pattern in either order, then either transferring the line patterns first into the interlayer dielectric layer forming line features or transferring the via pattern first into the interlayer dielectric layer as long as the patterns overlap to forming self aligned via features, depositing conducting metals and filling regions corresponding to the line and via features, and planarizing and removing excess metal from the line and via features.

### FIELD OF THE INVENTION

The present invention relates to interconnect structures and methods to generate interconnect structures that are part of integrated circuits and microelectronic devices.

### BACKGROUND OF THE INVENTION

The fabrication of Very-Large Scale Integrated (VLSI) or Ultra-Large Scale Integrated circuits (ULSI) requires an interconnect structure comprised of metallic wiring that connects individual devices in a semiconductor chip, to one another. Typically, the wiring interconnect network consists of two types of features that serve as electrical conductors: line features that traverse a distance across the chip, and via features which connect lines in different levels. Typically, the conducting metal lines and vias are comprised of aluminum or copper and are insulated by the interlayer dielectric (ILD) which are electrical insulators such as silicon dioxide (SiO₂) or fluorine or carbon doped silica film deposited by plasma enhanced chemical vapor deposition (PECVD).

In order to improve performance, the semiconductor industry has shrunk the gate length and as a result the chip size. As a consequence the interconnect structure that forms the metallic circuitry has also shrunk.

Traditionally, the via levels are one of the most challenging to print with a high process latitude. In order to improve the manufacturability of the lithography step, advanced masks that incorporate phase-shifting and optical proximity correction have been employed. In addition, as the size scale of these interconnects decrease, there is growing concern that overlay error between features in the interconnect structure may lead to reliability issues. Overlay errors result from misalignment during the lithography process as the mask invariably may not be perfectly aligned to the underlying structure. Although overlay errors can be minimized by reworking the lithography, some level of overlay error is unavoidable.

Two key failure modes for interconnects, that may be dependent on overlay error of lithographic patterns, are electromigration (EM) and time dependent dielectric breakdown (TDDB). This is of critical importance, as devices must be fabricated in a manner that enables their function over useful lifetimes and in various environments.

Electromigration failure results when a void forms in the conducting metal feature through metal diffusion leading to a short (or very high resistance) in the circuitry. The mechanism of electromigration is highly dependent upon the current density and consequently the cross section of the metal features are important. If the wiring is constructed such that the cross section of a wire is too small, high current densities may result leading to a wire that is prone to failure by electromigration.

Time dependent dielectric breakdown (TDDB) is a failure mode whereby the insulating materials (or layers) no longer serve as adequate electrical insulators resulting in unintended conductance between two adjacent metal features. This phenomenon is highly dependent upon the electrical field between the metal features as regions with higher electrical fields are more susceptible to TDDB failure. Consequently, the distance between metal features are critical to maintain as metal features that are too close may have very high electrical fields between them and may likely fail by TDDB.

There are numerous approaches to fabricate interconnect structures. One common approach is through the use of clustered hardmasks whereby the line (trench) and via pattern are first transferred into hardmask layers before transferring into the underlying interlayer dielectric. This is done by standard lithographic processes to define each of these patterns followed by a etch process such as reactive ion etching. One advantage of a use of a clustered hardmask scheme is that the resist can be stripped without significant exposure of the interlayer dielectric. This is a significant advantage over many commonly used integration schemes employing interlayer dielectrics that are prone to damage through this stripping process.

An example of a common clustered hardmask dual damascene approach is shown in FIG. 1 (A)-(H), including an overlay error. First in FIG. 1(A), the interlayer dielectric (100), an optional a polish stop layer (200), a via level hardmask (220), and a line level hardmask (240) are deposited on the substrate (10). The uppermost portion of the substrate (10) will typically be comprised of a cap barrier layer. In FIG. 1 (B) the line, or trench, lithography is performed and the line pattern (900) is transferred into line level hardmask (240) by, for example, reactive ion etch (RIE) and the excess resist from the line lithography is stripped. Next, as shown in FIG. 1 (C), the via lithography is performed using a resist (300) with the via pattern (920). In this example, the line lithography is performed prior to the via lithography, and this scheme is denoted as a line first clustered hardmask scheme. Subsequently, as shown in FIG. 1 (D), a via hardmask open step is performed wherein a via pattern (920) is transferred through the hardmask layers (220 and 240) in regions that coincide with the via pattern (920) using a nonselective etch process. Then as shown in FIG. 1 (E-G), the resist (300) is stripped and a selective etch is employed to partially etch the via pattern (920) into the interlayer dielectric (100). Finally, the line pattern (900) is transferred into the interlayer dielectric (100) and the via pattern (920) is simultaneously transferred through the remainder of the interlayer dielectric substrate and down to or into the substrate (10). Further, as shown in FIG. 1 (H), metal barrier liners (520) and conducting metal (500) are deposited into these features and the structure is planarized by chemical mechanical polishing to form an interconnect structure comprised of lines and vias that traverse parallel and perpendicular to the substrate, respectively, and a cap barrier (700) that serves as a copper and/or air diffusion barrier can be deposited atop the structure. This approach can be repeated to form a multilayer interconnect stack.

Of key importance to the above prior art scheme, is the high potential of overlay error of the via and line lithography (920 and 900, respectively) as shown in FIG. 1 (C-H). This is especially important for interconnects generated from fine lithography since poor overlay may lead to minimum distances between metal vias and adjacent lines that are too close and as set forth above may be prone to failure by TDDB.

A variation to the line first clustered hardmask scheme described above may be a prior art approach such as those described in U.S. Patent Application No 2006/______ (YOR920040539US1) and U.S. Patent Application No 2007/______ (YOR920050364US1) whereby a selective RIE process is instead used to transfer the via pattern (920) into the underlying structure. This selective RIE process is designed to etch the via hardmask layer (220), the polish stop layer (200) and partially into the interlayer dielectric (100) while the line hardmask layer (240) does not get etched appreciably. As a result, only a portion of the via pattern (920) is transferred into the underlying structure in subsequent etch processes. In implementing such a scheme, the overlay error between the via and line lithography does not result in a reduced minimum distance between line and via features since the line level hardmask prevents the underlying layers from being etched. However, the overlay error between the via and line lithography will result in a via cross section that is smaller then the intended size as dictated by the via pattern (920). This may be problematic as smaller via cross sections may result in high current densities that may cause the wiring to fail by electromigration (EM).

Many other dual damascene integration schemes exist whereby the order in which lithography and RIE is performed may differ. However, for each of these approaches, there are overlay errors that may lead to reduced minimum distances between metal features or reduced via cross sections. As device dimensions shrink, these overlay errors have become more critical and will continue to be critical for interconnects due to the inherent reliability issues associated with EM and TDDB.

Thus a need exists for an interconnect structure wherein the vias are generated through the economical lithographic method but without the problems of EM and TDDB.

### SUMMARY OF THE INVENTION

The invention solves the problems of lithographic generation of vias without EM or TDDB issues. The invention is an interconnect structure having partially self aligned vias with an interlayer dielectric layer on a substrate. The interlayer dielectric layer contains a multiple of conducting metal lines that traverse parallel to the substrate and two conducting metal vias that are orthogonal to the substrate.

The invention is also a method for fabricating an interconnect structure partially self aligned vias by depositing an interlayer dielectric onto a substrate, lithographically forming a via pattern that contains elongated via features and transferring the via pattern into the interlayer dielectric layer, lithographically forming a line pattern and transferring the line pattern into the interlayer dielectric layer, depositing a layer of conducting metals into the via and line features and then filling the via and line features, on top of the metal layer, and planarizing and removing excess metal from the via and line features.

Other and further objects, advantages and features of the present invention will be understood by reference to the following specification in conjunction with the annexed drawings, wherein like parts have been given like numbers.

### BRIEF DESCRIPTION OF THE DRAWINGS

FIG. 1 (A) through (H) is a schematic of the prior art showing the generation of an interconnect structure.

FIG. 2 (A) through (F) is a frontal view of a schematic of an embodiment of the present invention showing the generation of an interconnect structure partially self aligned vias using a via first scheme.

FIG. 3 (A) through (J) is a three dimensional view of an embodiment of the present invention showing the generation of an interconnect with partially self aligned vias using a via first scheme.

FIG. 4 (A) through (H) is a frontal view of a schematic of another embodiment of the present invention showing the generation of an interconnect structure with partially self aligned vias using a trench first scheme.

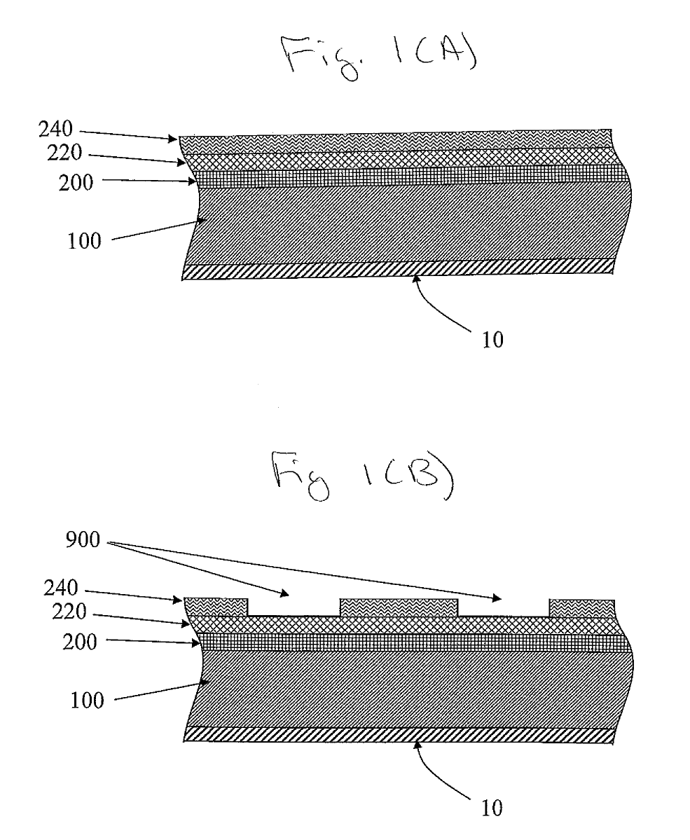

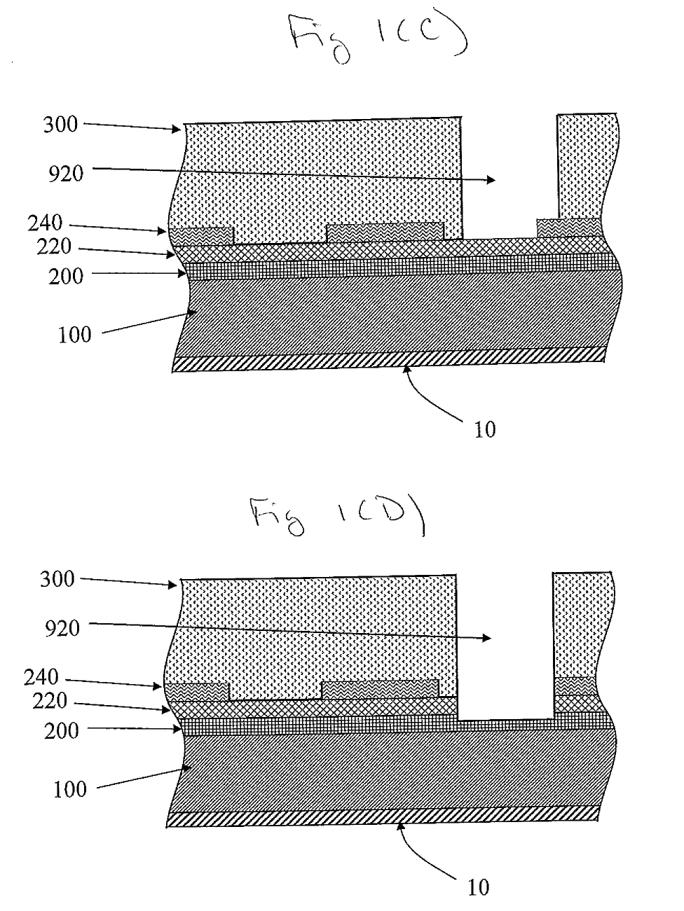

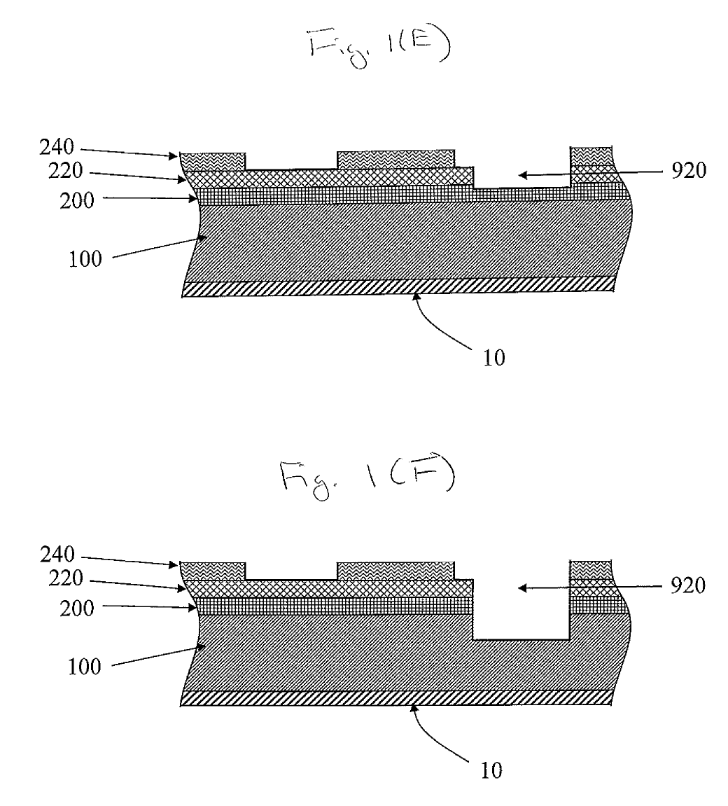

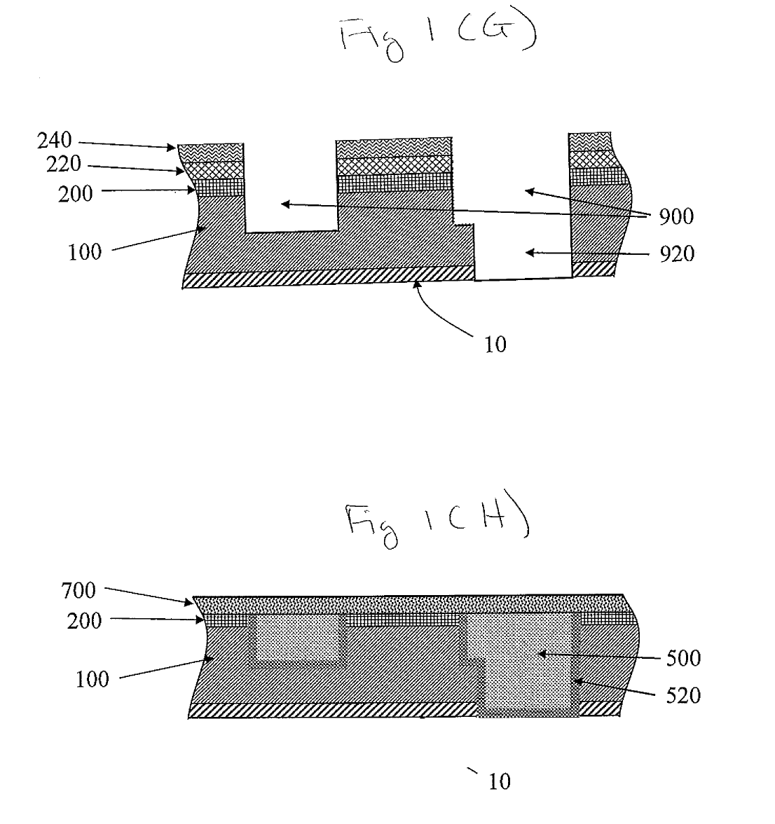

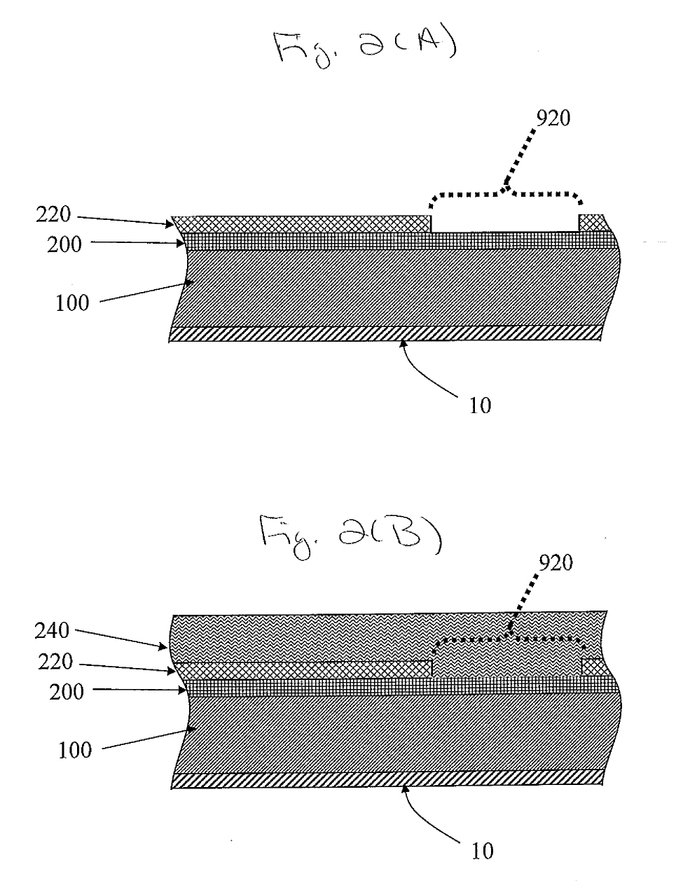

### DESCRIPTION OF THE PREFERRED EMBODIMENTS

To accomplish the objects of the invention and others, a dual damascene scheme involving partial self-alignment of vias is employed. The basis for the invention is the use of clustered hardmask approaches whereby (1) the via pattern is elongated in the direction orthogonal to the line pattern (metal line level above the via), (2) the line pattern is extended past the elongated via patterns, and (3) the transfer of these two patterns into the interlayer dielectric is completed in a manner that results in vias that are defined by the coincidence of the line and via pattern. Numerous methods in which these approaches can be applied are described and examples are outlined.

The invention is based on a utilization of two lithographic steps to pattern hardmask layers to produce interconnect structures having conducting metals vias that are partially self aligned to conducting metal lines. By repeating these processes, well defined interconnect structures having enhanced reliability can be achieved.

The reason for elongation of the via pattern and line pattern is to accommodate issues associated with mask alignment or overlay. Since, the vias will ultimately be defined by the coincidence of the via and line patterns, they will not have an elongated structure as defined by the via pattern. Instead, they will have a cross section that will be defined by the line width in the direction orthogonal to the line and the via pattern in the direction parallel to the line.

The elongation of the via pattern is performed in a manner to accommodate mask overlay errors, which may occur as part of the lithographic process. Ideally, the via pattern should be elongated so that in the instance where the line and via pattern have a maximum overlay error in the direction orthogonal to the line, the width of the via in the direction orthogonal to the line will still correspond to the line width. However, the via pattern must not be elongated excessively as this may lead to overlap of the via pattern with lines that are adjacent to the intended line that the via contacts in the event where maximum overlay error results.

The extension of the line pattern according to the method of the invention should be designed to accommodate the maximum overlay error in the direction parallel to the line. The extension of the line pattern is only performed in instances where the line terminates and a via is generated below the region corresponding to the line terminus. By extending these lines, the width of the final via in the direction parallel with the overlying line will be dictated by the width of the via pattern in the direction parallel with the line.

As the desired elongation of the vias and lines will be dependent upon the maximum overlay error in the direction orthogonal and parallel to the lines, respectively, the method of the invention and resulting inventive structure will minimize the overlay error. One means in which this can be accomplished is to directly align the line and via patterns directly to each other instead of underlying features. Otherwise, compounding overlay errors from multiple mask alignments may lead to a total overlay error between the line and via pattern that is excessively large.

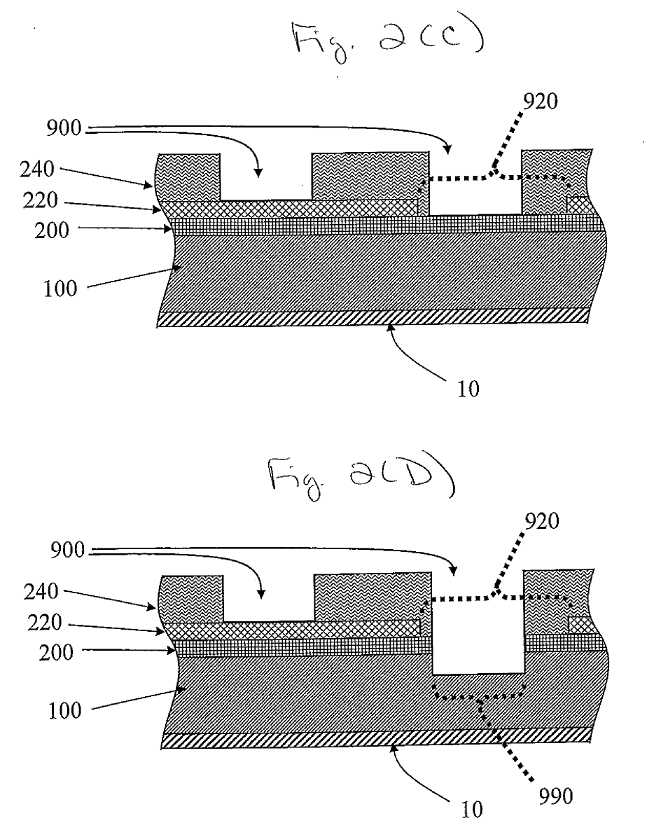

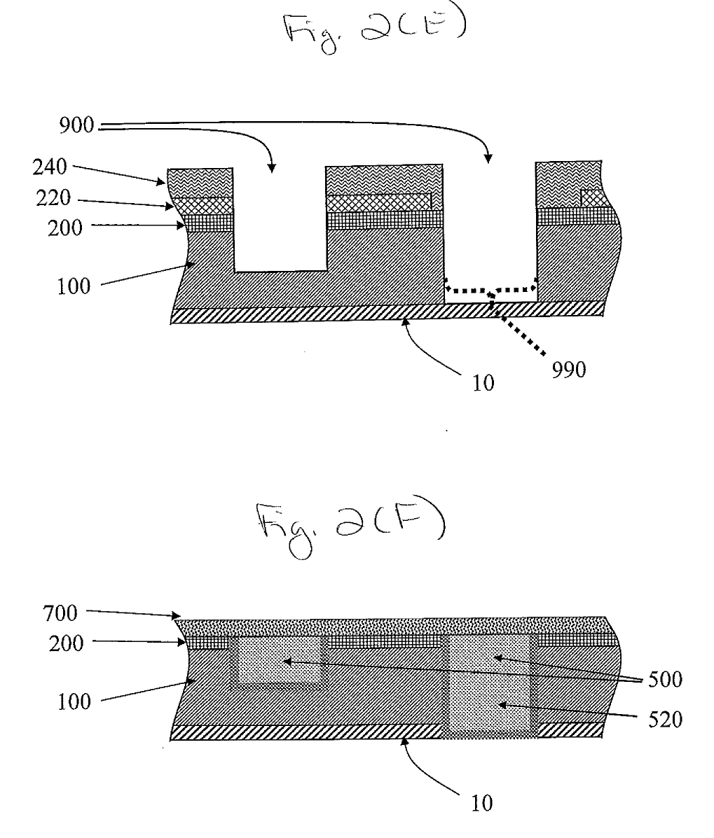

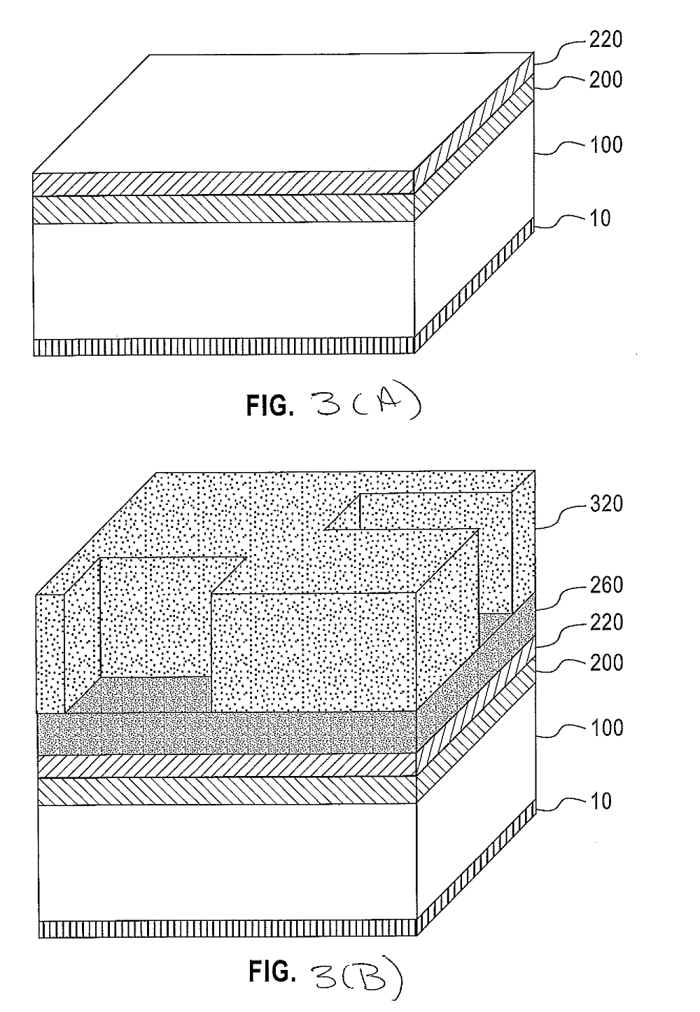

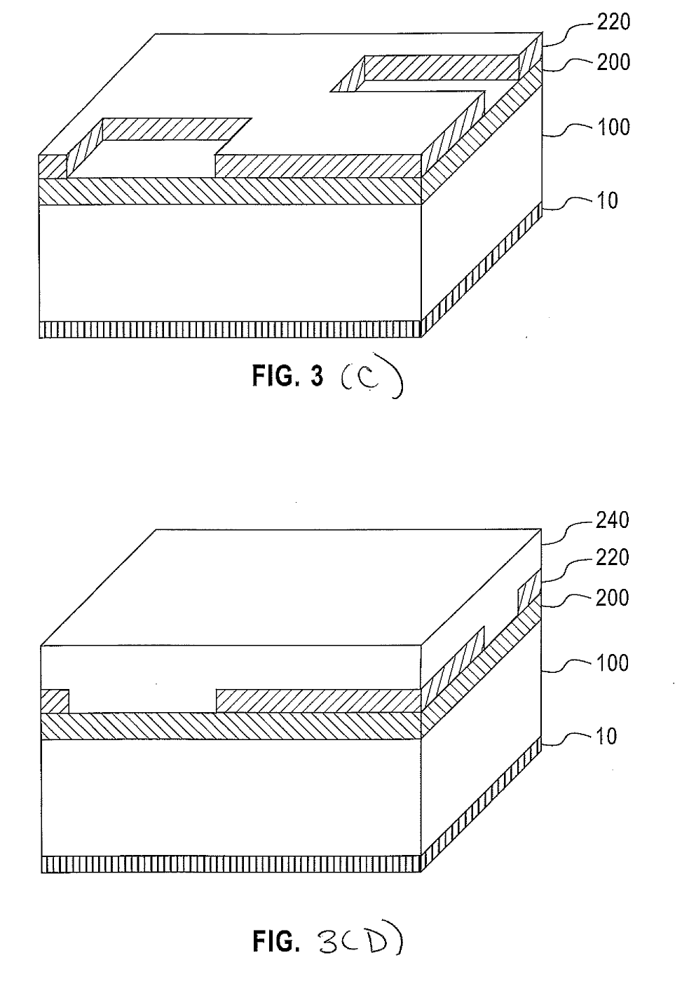

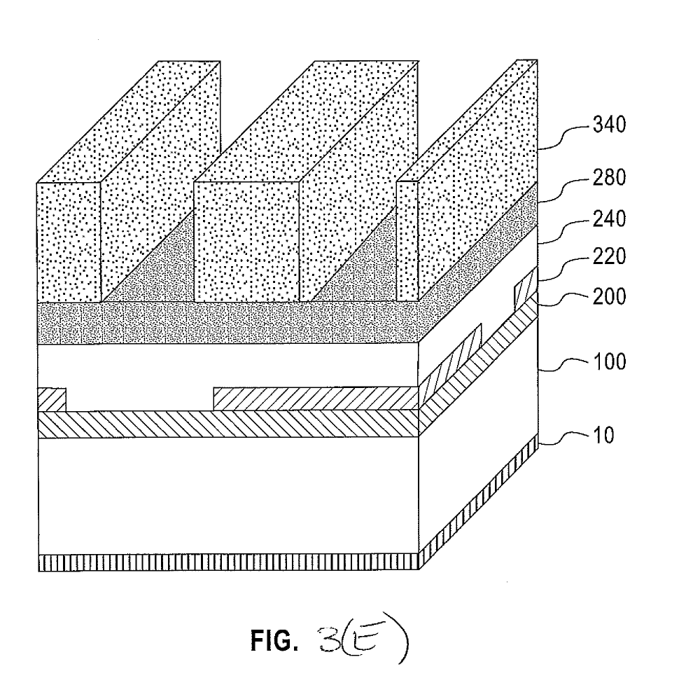

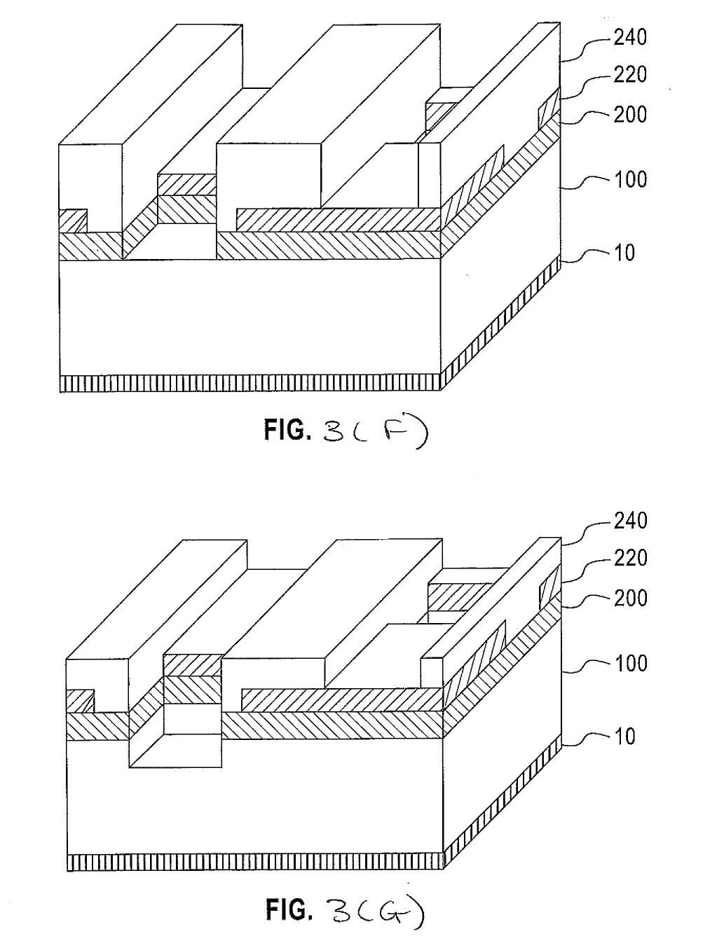

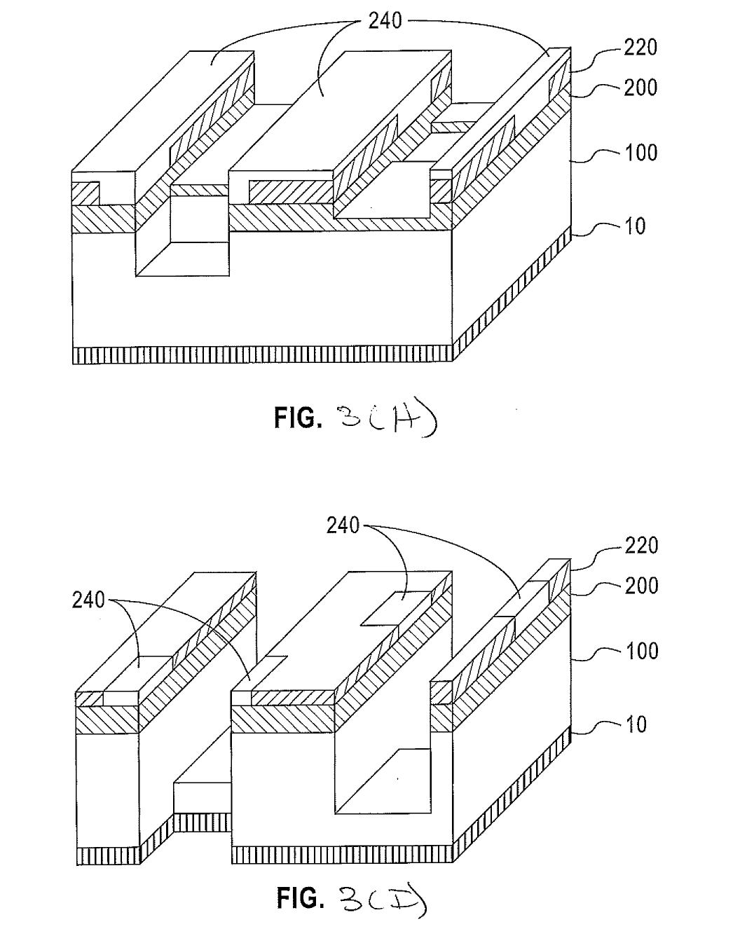

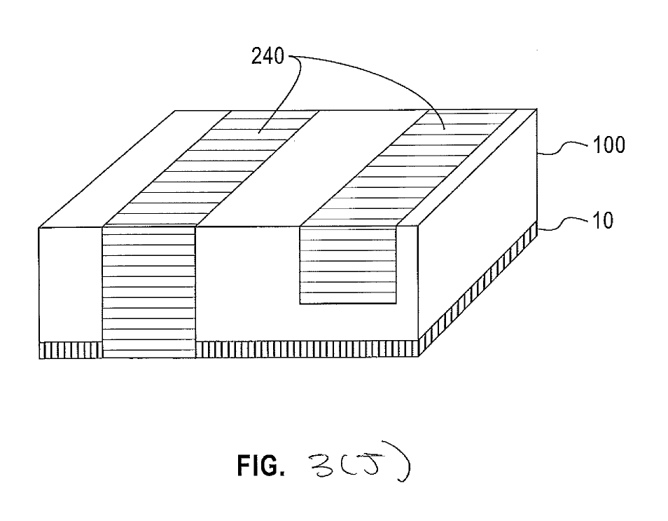

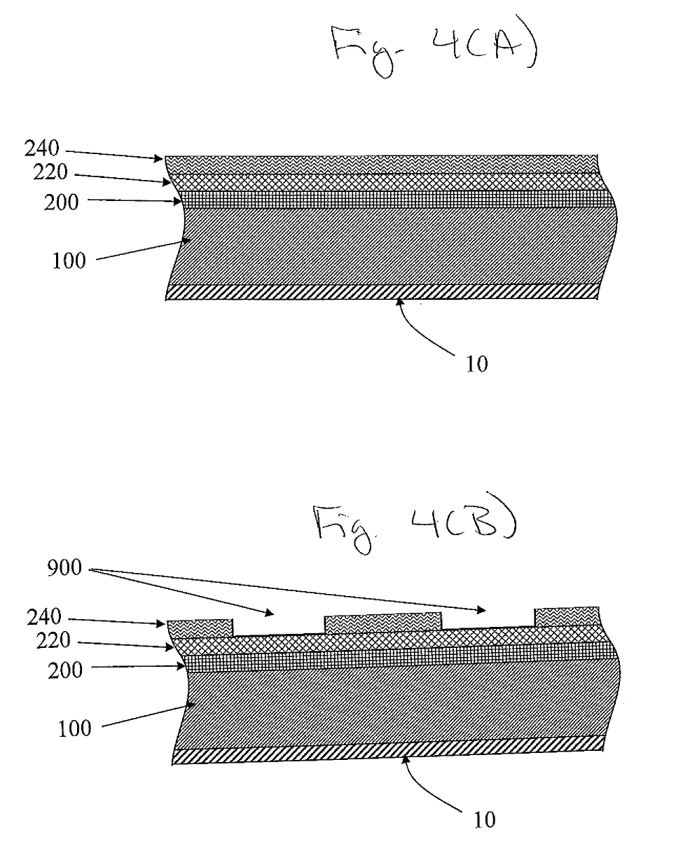

Referring to FIG. 2 (cross sectional view) and FIG. 3 (three dimensional view), the interconnect structure can be generated as having partially self-aligned vias with an exemplary via first approach. First, a dielectric layer (100), an optional a polish stop layer (200), and a via level hardmask (220) are deposited on the substrate (10). Next, as shown in FIG. 2 (A), via lithography is performed and the via pattern (920), comprised of vias that are elongated in a direction orthogonal to the subsequent line patterns (defined as the x-direction in FIG. 2), is transferred into via level hardmask (220), for example by reactive ion etch (RIE), and the excess resist from the via lithography is stripped. Next, as shown in FIG. 2 (B), a line level hardmask (240) is deposited and lithography is performed with a line pattern (900), and this pattern is transferred into the line level hardmask (240). Lines which terminate above a via have a line pattern (900) which is designed to extend past the elongated via pattern (920) in the direction orthogonal to the elongated via, defined as the y-direction in FIG. 2. Optionally, the resist having the line level pattern (900) may then be stripped as shown in FIG. 2 (C). As seen in FIG. 2 (D), a partial via etch, such as by RIE, may be employed to etch into the optional polish stop layer (200) and into the interlayer dielectric (100). It should be noted that this etch may occur only in regions where the line pattern (900) and via pattern (920) coincide and correspond to the partially self aligned via pattern (990). Optionally, the resist having the line level pattern (900) may be stripped next if not completed earlier. Next, as shown in FIG. 2 (E), an additional etch is employed to etch the line pattern (900) into the via level hardmask (220), the optional polish stop layer (200), and the interlayer dielectric layer (100). During this etch, the interlayer dielectric layer (100) in regions corresponding to the partially self aligned via pattern (990) will be further etched down to or into the substrate (10). Which may contain a cap barrier layer at the uppermost surface of the substrate (10). If the substrate (10) has an uppermost cap barrier layer, this cap barrier layer may be removed, by for example RIE, to open up underlying metal lines. Finally, as shown in FIG. 2 (F), metal barrier liners (520) and conducting metal (500) are deposited into these line and via features and the structure is planarized, such as by chemical mechanical polishing, to form an interconnect structure comprised of lines and vias that traverse parallel and perpendicular to the substrate, respectively, and a cap barrier (700) can be deposited atop the interconnect structure. This approach can be repeated to form a multilayer interconnect stack.

Referring to FIG. 3 (A) through (J) which is a cross sectional view of the structure of the present invention, the interconnect structure can be generated as having partially self-aligned vias with an exemplary via first approach. First, as shown in FIG. 3(A) (1) a dielectric layer (100), an optional a polish stop layer (200), and a via level hardmask (220) are deposited on the substrate (10). Next, as shown in FIG. 3(B) (2), via lithography is performed as seen in antireflective coating layer (260) and the resist pattern layer (320), the pattern comprised of vias that are elongated in a direction orthogonal to the subsequent line patterns (defined as the x-direction in FIG. 3). The pattern is then transferred into via level hardmask (220), for example by reactive ion etch (RIE), and the excess resist from the via lithography is stripped, as seen in FIG. 3(C) (3). Next, as shown in FIG. 3 (D) (4), a line level hardmask (240) is deposited. Lithography is performed in FIG. 3(E) (5) as seen in antireflective coating layer (280) and the resist pattern layer (340), with a line pattern. As seen in FIG. 3 (F) (6), this pattern is transferred into the line level hardmask (240) and in regions where the line and via pattern coincide, the optional hardmask (200) may be further etched. Lines which terminate above a via have a line pattern which is designed to extend past the elongated via pattern in the direction orthogonal to the elongated via, defined as the y-direction in FIG. 3. As seen in FIG. 3 (G) (7), a partial via etch, such as by RIE, may be employed to etch into through the optional polish stop layer (200) if not completed previously and into the interlayer dielectric (100). It should be noted that this etch may occur only in regions where the line pattern and via pattern coincide and correspond to the partially self aligned via pattern. Next, as shown in FIG. 3 (H) (8), an additional etch is employed to etch the line pattern through the via level hardmask (220), and into the optional polish stop layer (200), and the interlayer dielectric layer (100). Finally, as seen in FIG. 3 (I) (9), the interlayer dielectric layer (100) can be etched in regions corresponding to the line pattern while simultaneous etch of regions corresponding to the partially self aligned via pattern occurs down to or into the substrate (10), which may contain a cap barrier layer at the uppermost surface of the substrate (10). If the substrate (10) has an uppermost cap barrier layer, this cap barrier layer may be removed, by for example RIE, to open up underlying metal lines. Finally, as shown in FIG. 3 (J) (10), conducting metal (500) are deposited into these line and via features and the structure is planarized, such as by chemical mechanical polishing, to form an interconnect structure comprised of lines and vias that traverse parallel and perpendicular to the substrate, respectively, and a cap barrier can be deposited atop the interconnect structure. This approach can be repeated to form a multilayer interconnect stack.

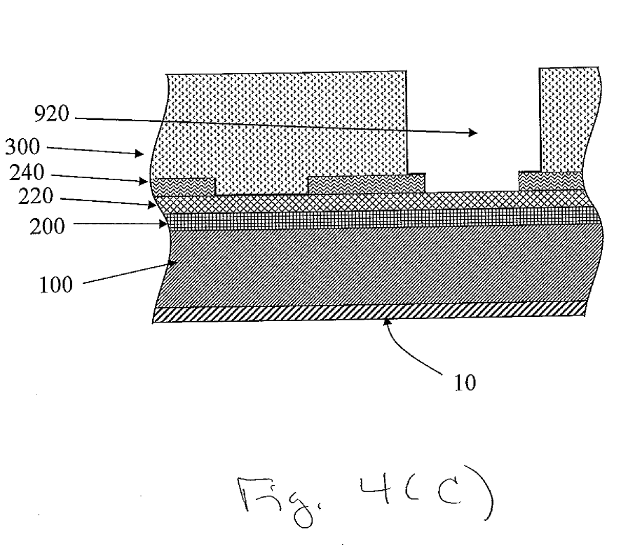

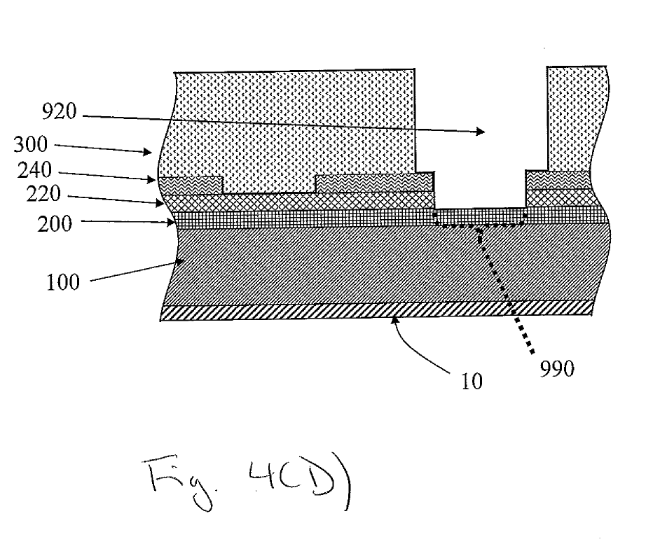

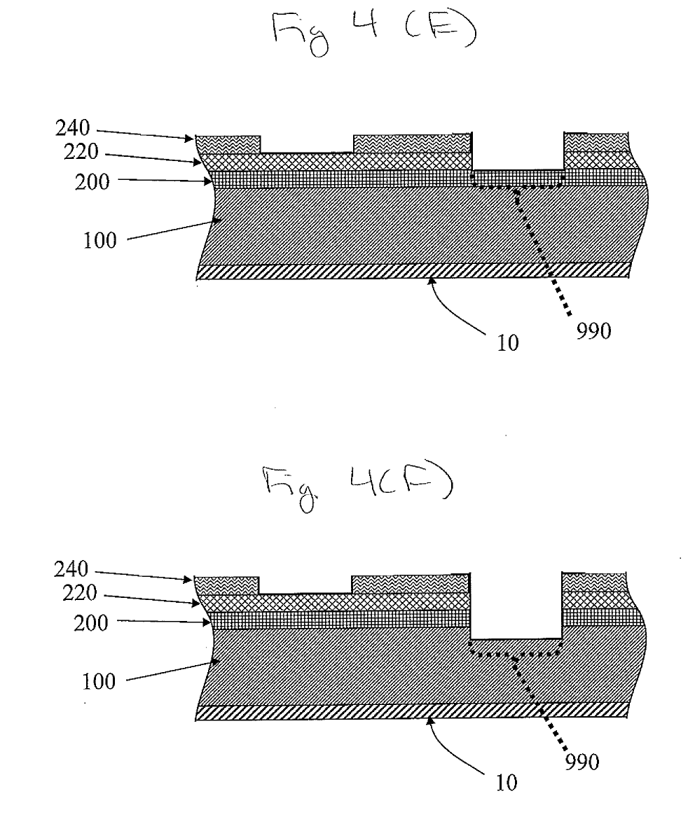

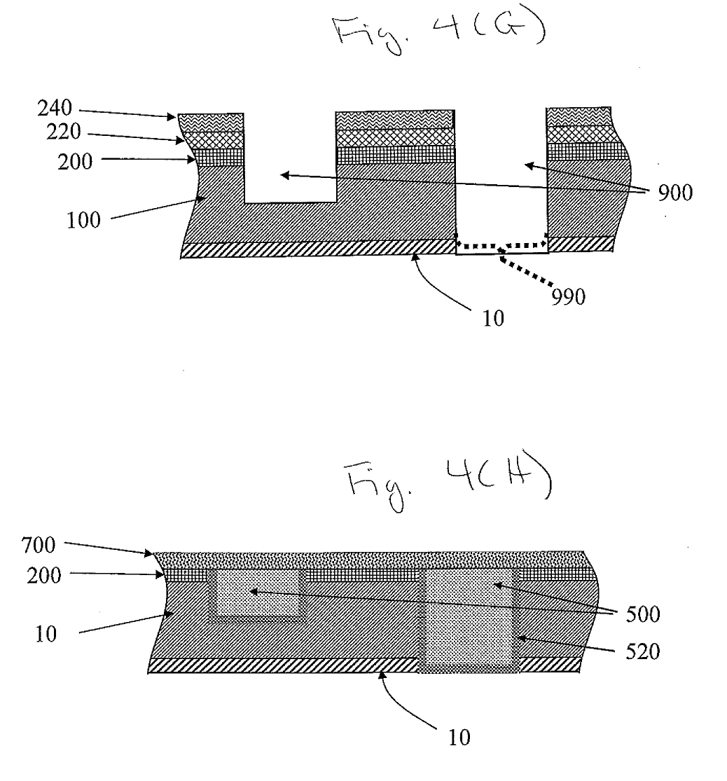

Referring to FIG. 4 (A) through (H) the interconnect structure can be generated in another way as having partially self-aligned vias with an exemplary line first approach. First, as shown in FIG. 4(A), the interlayer dielectric (100), an optional a polish stop layer (200), a via level hardmask (220), and a line level hardmask (240) are deposited on the substrate (10). FIG. 4(B) shows where line, or otherwise referred to as trench lithography is performed and the line pattern (900) is transferred into line level hardmask (240), by for example RIE, and any excess resist from the line lithography is stripped. Again, for lines that terminate above a via, the line pattern (900) is designed to extend past the elongated via pattern (920), that will be incorporated subsequently, in the direction orthogonal to the elongated via. Next, as shown in FIG. 4(C), via lithography is performed, for example by using a resist (300), with the via pattern (920) having vias that are elongated in the direction orthogonal to the corresponding line pattern (900). As seen in FIG. 4(D), a via hardmask open etch is employed wherein the via pattern (920) is transferred through the via hardmask layer (220), for example using a selective RIE process that may etch through the via hardmask layer (220) but will not appreciably etch the line hardmask layer (240). As seen in FIG. 4(E), next the resist (300) can optionally be stripped and then as seen in FIG. 4(F) a selective etch process may be employed to further transfer the self aligned via pattern (990) through the optional polish stop layer (200) and partially into the interlayer dielectric (100).

As the line hardmask layer (240) in this method may serve as an etch mask layer during the process, the self aligned via pattern (990) that gets transferred into the underlying layers corresponds to the coincidence of the via and line patterns (900 and 920, respectively). As seen in FIG. 4 (G) an additional etch is then be employed to etch the line pattern (900) through the via level hardmask (220), the optional polish stop layer (200), and the into the interlayer dielectric (100). During this etch process, the interlayer dielectric (100) in regions corresponding to the self aligned via pattern (990) will be further etched down to or into the substrate (10). Finally, as seen in FIG. 4 (H), metal barrier liners (520) and conducting metal (500) are deposited into these features, and the structure is planarized by chemical mechanical polishing to form an interconnect structure comprised of lines and vias that traverse parallel and perpendicular to the substrate, respectively. A cap barrier (700) may be deposited atop the interconnect structure. This approach can be repeated to form a multilayer interconnect stack.

In the interconnect structure of the present invention, since the vias are elongated in a direction orthogonal to the line pattern and the line pattern is extended pass the elongated vias in the via pattern, a narrowed via may not result in instances where there is overlay error. The via cross section will be defined by the line width in the direction orthogonal to the line and the via pattern in the direction parallel to the line.

Turning to the structure, the substrate of the present invention can be comprised of Si, SiGe or SGOI, SOI, SiC, SCOI, SiGeC, SGCOI, III-V, II-VI semiconducting material, or any permutations thereof.

Suitable interlayer dielectrics include but are not limited to porous dielectric or low-K dielectrics. The interlayer dielectric preferably will have a low dielectric constant that may be in the range of about k=1.5 and about k=4.0. For example, the interlayer dielectrics include dielectrics that may be deposited by spin coating such as polyarylenes, polyarylene ethers, polysilsequioxanes, and polycarbosilanes or CVD deposited dielectrics having compositions comprised of carbon doped oxides or SiCOH. The interlayer dielectric may or may not be porous.

The etchant to be used in the inventive method can be reactive ions, molecular ion beam, wet etchants and combinations thereof.

The various hardmasks employed in the invention may metal or not. Those including metal may contain TiN, TaN, TiOx, W, WN, HfOx, Cu, Ru, Ti, ZrO₂ or combinations thereof. Hardmasks not containing metal may also be used and these may include SiN, SiO2, SiC, SiGN, SiON, BN, SiNCH, SiCOH and combinations thereof. The hardmask may be deposited by spin coating, chemical vapor deposition or any known method. The hardmask layers should have attributes, known by those in the art, in order to withstand lithographic rework processes and should have suitable adhesion to adjacent layers in order to withstand typical interconnect fabrication processes without interfacial failure (e.g., delamination). In embodiments of the invention employing RIE, the primarily function of the hardmask is to provide etch contrast during RIE to transfer the line or self aligned via patterns into the underlying dielectric. In these embodiments, it is preferred that the hardmask will not etch, or etch at only a very low rate, during these processes.

In another embodiment of the invention, one of the hardmasks for the above examples can be omitted by using the resist as an etch mask to transfer the line and via patterns into the interlayer dielectric instead so as to allow the omission of the topmost hardmask layer. In certain structures, a strip step may be required to strip excess resist with the interlayer dielectric exposed.

Optionally, antireflective layers may be employed under the resist layers in the above examples. These materials are commonly utilized to enhance the process window of the resist layers and eliminate reflectance issues that may lead to standing waves.

The interconnect structures and methods of the present invention can be employed in any microelectronic device including but not limited to high speed microprocessors, application specific integrated circuits (ASICs), memory storage and the like.

The inventive interconnect structure and method may be applied to other dual damascene integration approaches known in the art, for example, in interconnect structures having hybrid interlayer dielectrics whereby the interlayer dielectric is comprised of a bilayer of two distinct materials with one layer roughly corresponding to the line thickness and the other dielectric corresponding roughly to the via thickness. Further, the inventive interconnect structure and method may be applied to interconnect structures employing a buried etch stop layer, whereby the interlayer dielectric is comprised of a trilayer of at least two distinct materials where the middle layer is the buried etch stop layer. In such a case, the buried etch stop layer is placed at or near the position corresponding to the bottom of the line and may facilitate the definition of the interconnect structure. For such an embodiment the dielectric above and below the buried etch stop may be identical or dissimilar.

The invention increases reliability of BEOL structures by minimizing structural errors related to misalignment in masking layers that are invariable in interconnect fabrication. The invention will reduce two issues simultaneously that are critical for reliability especially as interconnect dimensions decrease. First, the invention results in improved control of the minimum space between metal features that may result through the compounding of misalignment errors, thus reducing TDDB or other related failure mechanisms. Second, this integration approach provides a pathway in which narrowed vias (vias w/smaller cross sections) do not form resulting in reduced electromigration.

The process and structure of the present invention is further illustrated by the following non-limiting examples.

### Example 1

A dielectric layer, an optional a polish stop layer, and a via level hardmask are deposited onto a silicon substrate. Through lithography, vias are patterned into the hardmasks, with the via pattern elongated in a direction orthogonal to the subsequent line patterns. The pattern is transferred by reactive ion etch and the excess resist from the via lithography is stripped. Next, a line level hardmask is deposited and patterned with lines via lithography. The line pattern is transferred into the line level hardmask by reactive ion etch and the excess resist is stripped. Lines which terminate above a via are to be patterned in a line pattern which is designed to extend past the elongated via pattern in the direction orthogonal to the elongated via. Another reactive ion etch is used to partially etch a via, into the optional polish stop layer and, into the interlayer dielectric layer. This etch step only occurs only in regions where the line pattern and via pattern coincide and correspond to the partially self aligned via pattern. An additional etch is employed to etch the line pattern into the via level hardmask, the optional polish stop layer and, the interlayer dielectric layer. During this etch step, the interlayer dielectric layer in regions corresponding to the partially self aligned via pattern will be further etched down to the substrate. Metal barrier liners and conducting metal are deposited into these line and via features and the structure is planarized by chemical mechanical polishing to form an interconnect structure comprised of lines and vias that traverse parallel and perpendicular to the substrate, respectively.

### Example 2

A dielectric layer, a polish stop layer, and a via level hardmask and line level hardmask are deposited onto a silicon substrate. Through lithography a line pattern is transferred into line level hardmask by RIE, and any excess resist from the line lithography is stripped. The line pattern is set to extend past an elongated via pattern that is employed next in the process, with the lines in the direction orthogonal to the elongated via. Via lithography is then performed using a resist and the via pattern includes vias that are elongated in the direction orthogonal to the corresponding line pattern. Via hardmask open etch is employed wherein the via pattern is transferred through the via hardmask layer by a selective RIE process but did not appreciably etch the line hardmask layer. The resist is stripped. A selective etch process transfers the self aligned via pattern through the polish stop layer and partially into the interlayer dielectric.

The self aligned via pattern is transferred into the underlying layers corresponding to the coincidence of the via and line pattern. The line pattern is etched through the via level hardmask, the polish stop layer, and the into the interlayer dielectric. During this etch, the interlayer dielectric in regions corresponding to the self aligned via pattern are further etched into the substrate. Metal barrier liners and conducting metal are deposited into the features, and the structure is planarized by chemical mechanical polishing. A cap barrier is deposited on top of the resulting interconnect structure. An interconnect structure comprised of lines and vias that traverse parallel and perpendicular to the substrate, respectively, is generated.

A multilayer interconnect stack may be generated by repeating the steps in Example 2 on the resulting interconnects structures.

The invention has been described in terms of preferred embodiments thereof, but is more broadly applicable as will be understood by those skilled in the art. The scope of the invention is only limited by the following claims.

1. An interconnect structure having partially self aligned vias comprising:
(a) a substrate; and
(b) an interlayer dielectric layer on the substrate wherein the interlayer dielectric layer contains (i) at least two conducting metal lines that traverse parallel to the substrate and (ii) at least two conducting metal vias that are orthogonal to the substrate.

2. The structure of claim 1 wherein the interlayer dielectric layer has a dielectric constant of about 1.5 to about 4.0.

3. The structure of claim 1 wherein the interlayer dielectric layer is porous (or non porous) and selected from polyarylenes, polyarylenethers, polysilesquioxane, polycarbosilanes, carbon doped oxides, SiCOH, and combinations thereof.

4. The structure of claim 1, further comprising a chemical mechanical polish stop layer on top of the interlayer dielectric layer.

5. The structure of claim 1, wherein the interlayer dielectric layer is comprised of two layers of dielectric wherein the top dielectric layer has a thickness that corresponds to the metal line height in the interlayer dielectric layer and the bottom dielectric layer has a thickness that corresponds to the metal via height.

6. The structure of claim 1, further comprising an etch stop layer in the interlayer dielectric layer that is about at the position corresponding to the bottom of the metal line.

7. The structure of claim 1 wherein the dielectric between the metal lines are comprised of dielectrics selected from the group consisting of silicon oxide, carbon doped oxides, silsesquioxanes, siloxanes, polycarbosilanes, polyarylenes, and combinations thereof.

8. The structure of claim 1 wherein the dielectric between the metal vias are comprised of dielectrics selected from the group consisting of silicon oxide, carbon doped oxides, silsesquioxanes, siloxanes, polycarbosilanes, polyarylenes, and combinations thereof.

9. The structure of claim 1 further containing at least one dielectric or metal containing hardmask on the interlayer dielectric layer.

10. The structure of claim 9 wherein the hardmask is selected from the group consisting of SiN, SiO₂, SiON, SiC, SiCN, SiCNH, TaN, TiN, TaC, TiC, TaCN, TaCNH, TiCN, TiCNH, W, WN, HfOx, Cu, Ru, Ti, ZrO₂, and combinations thereof.

11. A method for fabricating an interconnect structure partially self aligned vias comprising:
a) depositing an interlayer dielectric layer onto a substrate;
b) depositing at least one hardmask onto the interlayer dielectric layer;
c) lithographically forming a first pattern that contains elongated via features;
d) lithographically forming a second pattern that contains line features;
e) transferring the second pattern into the interlayer dielectric layer forming line features;
f) transferring a pattern into the interlayer dielectric layer where the pattern corresponds to where the first pattern and second pattern overlap forming self aligned via features;
g) depositing conducting metals onto the substrate filling regions corresponding to the line and via features;
h) filling the line and via features on top of the metal layer in the via and line features; and
i) planarizing and removing excess metal from the line and via features.

12. The method of claim 11 wherein the hardmask is selected from the group consisting of SiN, SiO₂, SiON, SiC, SiCN, SiCNH, TaN, TiN, TaC, TiC, TaCN, TaCNH, TiCN, TiCNH, W, WN, HfOx, Cu, Ru, Ti, ZrO₂, and combinations thereof.

13. The method of claim 11 further comprising depositing a cap barrier layer on top of the interconnect structure having exposed metal lines.

14. The method of claim 11, wherein the interlayer dielectric layer is a hybrid structure comprised of two dielectrics wherein the top dielectric layer has a thickness that corresponds to the metal line height in the interlayer dielectric layer and the bottom dielectric layer has a thickness that corresponds to the metal via height.

15. The method of claim 13 further comprising a third dielectric forming an etch stop layer to define the bottom of the line features.

16. The method of claim 11 further comprising depositing a second hardmask layer on the interlayer dielectric layer.

17. The method of claim 11 further comprising depositing a chemical mechanical polish stop layer on the interlayer dielectric layer.

18. The method of claim 17 further comprising depositing a second hardmask layer on the chemical mechanical polish stop layer.

19. The method of claim 18 wherein the second hardmask is deposited after transfer of the line pattern into the interlayer dielectric layer.

20. The method of claim 18 wherein the second hardmask is deposited after transfer of the via pattern into the interlayer dielectric layer.

21. The method of claim 11 further comprising depositing a cap barrier layer on the interlayer dielectric layer and conducting metal lines after the planarizing step (i)

22. The method of claim 11 wherein the method is repeated to form a multilayer stack.

23. The method of claim 11 wherein the dielectric between the metal lines are comprised of dielectrics selected from the group consisting of silicon oxide, carbon doped oxides, silsesquioxanes, siloxanes, polycarbosilanes, polyarylenes, and combinations thereof.

24. The method of claim 11 wherein the dielectric between the metal vias are comprised of dielectrics selected from the group consisting of silicon oxide, carbon doped oxides, silsesquioxanes, siloxanes, polycarbosilanes, polyarylenes, and combinations thereof.

25. A method for fabricating an interconnect structure partially self aligned vias comprising:
a) depositing an interlayer dielectric layer onto a substrate;
b) depositing at least one hardmask onto the interlayer dielectric layer;
c) lithographically forming a first pattern that contains line features;
d) lithographically forming a second pattern that contains elongated via features;
e) transferring the second pattern into the interlayer dielectric layer forming elongated via features;
f) transferring a pattern into the interlayer dielectric layer where the pattern corresponds to where the first pattern and second pattern overlap forming self aligned via features;
g) depositing conducting metals onto the substrate filling regions corresponding to the line and via features;
h) filling the line and via features on top of the metal layer in the via and line features; and
i) planarizing and removing excess metal from the line and via features.

26. The method of claim 25 wherein the hardmask is selected from the group consisting of SiN, SiO₂, SiON, SiC, SiCN, SiCNH, TaN, TiN, TaC, TiC, TaCN, TaCNH, TiCN, TiCNH, W, WN, HfOx, Cu, Ru, Ti, ZrO₂, and combinations thereof.

27. The method of claim 25 further comprising depositing a cap barrier layer on top of the interconnect structure having exposed metal lines.

28. The method of claim 25, wherein the interlayer dielectric layer is a hybrid structure comprised of two dielectrics wherein the top dielectric layer has a thickness that corresponds to the metal line height in the interlayer dielectric layer and the bottom dielectric layer has a thickness that corresponds to the metal via height.

29. The method of claim 27 further comprising a third dielectric forming an etch stop layer to define the bottom of the line features.

30. The method of claim 25 further comprising depositing a second hardmask layer on the interlayer dielectric layer.

31. The method of claim 25 further comprising depositing a chemical mechanical polish stop layer on the interlayer dielectric layer.

32. The method of claim 31 further comprising depositing a second hardmask layer on the chemical mechanical polish stop layer.

33. The method of claim 32 wherein the second hardmask is deposited after transfer of the line pattern into the interlayer dielectric layer.

34. The method of claim 32 wherein the second hardmask is deposited after transfer of the via pattern into the interlayer dielectric layer.

35. The method of claim 25 further comprising depositing a cap barrier layer on the interlayer dielectric layer after the planarizing step (i).

36. The method of claim 25 wherein the method is repeated to form a multilayer stack.

37. The method of claim 25 wherein the dielectric between the metal lines are comprised of dielectrics selected from the group consisting of silicon oxide, carbon doped oxides, silsesquioxanes, siloxanes, polycarbosilanes, polyarylenes, and combinations thereof.

38. The method of claim 25 wherein the dielectric between the metal vias are comprised of dielectrics selected from the group consisting of silicon oxide, carbon doped oxides, silsesquioxanes, siloxanes, polycarbosilanes, polyarylenes, and combinations thereof.

39. A multilayer stack comprised on the interconnect structures of claim 1.
